(19) United States
(12) Patent Application Publication
(10) Pub. No.: US 2024/0413056 A1
(43) Pub. Date: Dec. 12, 2024

(54) CAPACITOR COMPONENT

(71) Applicant: SAMSUNG ELECTRO-MECHANICS CO., LTD., Suwon-si (KR)

(72) Inventors: Chi Hyeon JEONG, Suwon-si (KR); Hyun Sang KWAK, Suwon-si (KR); Seong Hwan LEE, Suwon-si (KR); Hyun Goo JEON, Suwon-si (KR)

(73) Assignee: SAMSUNG ELECTRO-MECHANICS CO., LTD., Suwon-si (KR)

(21) Appl. No.: 18/433,895

(22) Filed: Feb. 6, 2024

(30) Foreign Application Priority Data
Jun. 12, 2023 (KR) 10-2023-0074866

(51) Int. Cl. H01L 23/48; H01L 23/64

(52) U.S. Cl. CPC H01L 23/481; H01L 23/642; H01L 28/86; H01L 28/90

(57) ABSTRACT

A capacitor component includes a substrate having first and second surfaces opposing each other, a first interlayer disposed on the first surface of the substrate, the first interlayer including a first trench, a first trench capacitor disposed in the first trench, a second interlayer disposed on the second surface of the substrate, the second interlayer including a second trench, a second trench capacitor disposed in the second trench, and a through-via passing through the substrate to connect the first trench capacitor and the second trench capacitor to each other.

### CROSS-REFERENCE TO RELATED APPLICATION(S)

This application claims benefit of priority to Korean Patent Application No. 10-2023-0074866 filed on Jun. 12, 2023 in the Korean Intellectual Property Office, the disclosure of which is incorporated herein by reference in its entirety.

### TECHNICAL FIELD

The present disclosure relates to a capacitor component.

Recently, portable IT products such as smartphones and wearable devices have been reduced in thickness, resulting in an increase in a need for reducing thicknesses of passive elements to reduce a thickness of an overall package. To this end, research into thin film silicon capacitors, capable of achieving a further reduced thickness than multilayer ceramic capacitors (MLCC), has been actively conducted.

Such thin film silicon capacitors have the disadvantage of having lower capacitance relative to a mounting area, as compared to multilayer ceramic capacitors according to the related art. Therefore, it is necessary to conduct research into thin film silicon capacitors having high capacitance relative to the same mounting area.

### SUMMARY

An aspect of the present disclosure provides a capacitor component having high capacitance per unit area.

The aspects of the present disclosure are not limited to those set forth herein, and will be more easily understood in the course of describing specific example embodiments.

According to an aspect of the present disclosure, there is provided a capacitor component including a substrate having first and second surfaces opposing each other, a first interlayer disposed on the first surface of the substrate, the first interlayer including a first trench, a first trench capacitor disposed in the first trench, a second interlayer disposed on the second surface of the substrate, the second interlayer including a second trench, a second trench capacitor disposed in the second trench, and a through-via passing through the substrate to connect the first trench capacitor and the second trench capacitor to each other.

According to example embodiments of the present disclosure, a capacitor component may have high capacitance per unit area.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view of a capacitor component according to an example embodiment of the present disclosure;

FIG. 2 is a schematic cross-sectional view taken along line I-I′ of FIG. 1;

FIG. 3 is a schematic cross-sectional view taken along line II-II′ of FIG. 2;

FIG. 4 is a modification of FIG. 3;

FIG. 5 is a modification of FIG. 2;

FIG. 6 is a schematic plan view of a capacitor component according to another example embodiment of the present disclosure;

FIG. 7 is a schematic cross-sectional view taken along line III-III′ of FIG. 6;

FIG. 8 is a schematic cross-sectional view taken along line IV-IV′ of FIG. 6; and

FIGS. 9 to 15 are cross-sectional views of main processes of a method of manufacturing a capacitor component according to an example embodiment of the present disclosure.

### DETAILED DESCRIPTION

Hereinafter, example embodiments of the present disclosure are described with reference to the accompanying drawings. The present disclosure may, however, be exemplified in many different forms and should not be construed as being limited to the specific example embodiments set forth herein. In addition, example embodiments of the present disclosure may be provided for a more complete description of the present disclosure to those skilled in the art. Accordingly, the shapes and sizes of the elements in the drawings may be exaggerated for clarity of description, and elements denoted by the same reference numerals in the drawings may be the same elements.

In order to clearly illustrate the present disclosure, portions not related to the description are omitted, and sizes and thicknesses are magnified in order to clearly represent layers and regions, and similar portions having the same functions within the same scope are denoted by similar reference numerals throughout the specification. Throughout the specification, when an element is referred to as “comprising” or “including,” it means that it may include other elements as well, rather than excluding other elements, unless specifically stated otherwise.

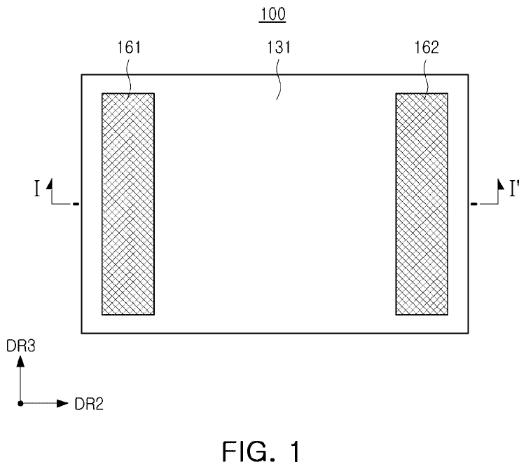

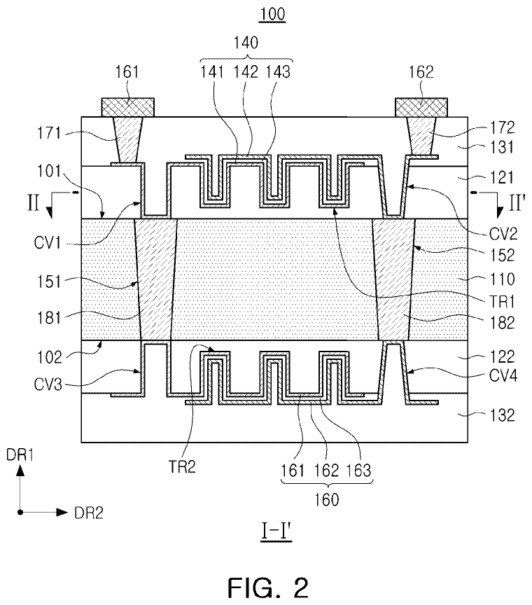

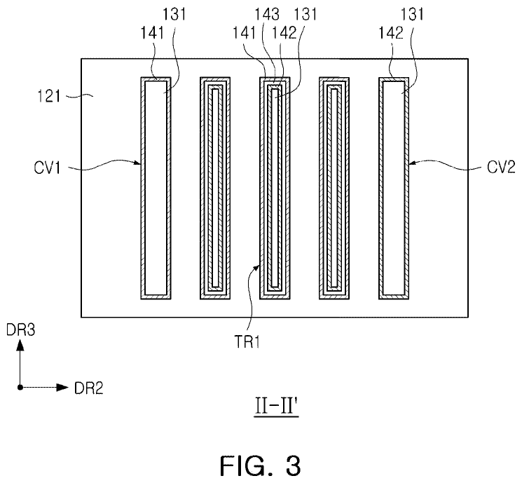

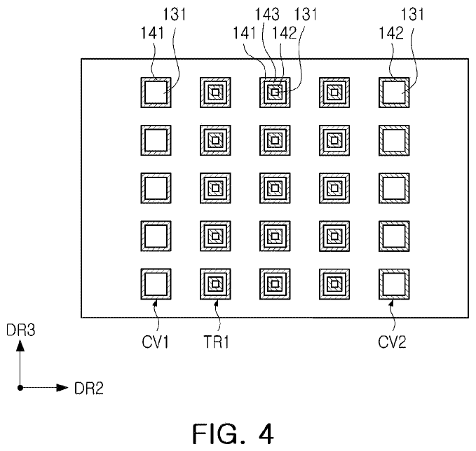

FIG. 1 is a schematic plan view of a capacitor component according to an example embodiment of the present disclosure. FIG. 2 is a schematic cross-sectional view taken along line I-I′ of FIG. 1. FIG. 3 is a schematic cross-sectional view taken along line II-II′ of FIG. 2. FIG. 4 is a modification of FIG. 3.

Referring to FIGS. 1 and 2, a capacitor component 100 according to an example embodiment of the present disclosure may include a substrate 110, interlayers 121 and 122, trench capacitors 140 and 160, and through-vias 151 and 152.

The substrate 110 may have a first surface 101 and a second surface 102 opposing each other in a first direction DR1. The substrate 110 may include a semiconductor material, such as a Group IV semiconductor, a Group III-V compound semiconductor, or a Group II-IV compound semiconductor. For example, Group IV semiconductors may include silicon, germanium, or silicon-germanium. The substrate 110 may be provided as, for example, a bulk wafer, but the present disclosure is not limited thereto.

A first interlayer 121 may be disposed on the first surface 101 of the substrate 110, and may include a first trench TR1. A second interlayer 122 may be disposed on the second surface 102 of the substrate 110, and may include a second trench TR2. The interlayers 121 and 122 may include an insulating material, such as oxide, nitride, or a combination thereof. The interlayers 121 and 122 may include, for example, an oxide film of the substrate 110 or a native oxide film of the substrate 110.

The interlayers 121 and 122 including oxide and/or nitride may have an etching rate higher than that of the substrate 110, and an amount of etching may be more accurately controlled. Accordingly, the trenches TR1 and TR2 may be formed in the interlayers 121 and 122 using an etching process or the like, thereby securing process ease and process accuracy, as compared to the trenches TR1 and TR2 formed in the substrate 110.

The first trench TR1 may extend from one surface of the first interlayer 121 toward the first surface 101 of the substrate 110 in the first direction DR1. The second trench TR2 may extend from one surface of the second interlayer 122 toward the second surface 102 of the substrate 110 in the first direction DR1.

The number or arrangement of the first and second trenches TR1 and TR2 does not need to be particularly limited. It may be sufficient as long as at least one of each of the first and second trenches TR1 and TR2 is disposed. However, the first interlayer 121 may preferably include a plurality of first trenches TR1, and the second interlayer 122 may preferably include a plurality of second trenches TR2. A height of each of the first and second trenches TR1 and TR2 in the first direction DR1 does not need to be particularly limited, and may be tens of nm to tens of μm depending on a size or target capacitance of the capacitor component 100.

It is illustrated that the first and second trenches TR1 and TR2 have a cross-section having a rectangular shape, but the present disclosure is not limited thereto. The first and second trenches TR1 and TR2 may have cross-sections having various shapes such as circular, elliptical, and trapezoidal shapes. In addition, the first and second trenches TR1 and TR2 may have inclined side surfaces such that widths thereof decrease toward the first and second surfaces 101 and 102 of the substrate 110, respectively, due to aspect ratios thereof. The first and second trenches TR1 and TR2 may have convex curved lower surfaces toward the first and second surfaces 101 and 102, respectively, but the present disclosure is not limited thereto.

Referring to FIG. 3, the plurality of first trenches TR1 may be disposed to be spaced apart from each other in a second direction DR2, intersecting the first direction DR1, and each of the plurality of first trenches TR1 may extend in a third direction DR3, intersecting the first and second directions DR1 and DR2. However, the present disclosure is not limited thereto. For example, as illustrated in FIG. 4, in an example embodiment, the plurality of first trenches TR1 may be disposed to be spaced apart from each other in the second direction DR2 and the third direction DR3. In addition, the second trench TR2 may be symmetrical to the first trench TR1 in the first direction DR1, and thus the above description of the shape of the first trench TR1 may be applied to the second trench TR2 in the same manner.

Referring to FIG. 2, a first trench capacitor 140 may be disposed in the first trench TR1, and a second trench capacitor 160 may be disposed in the second trench TR2. Shapes of the first and second trench capacitors 140 and 160 do not need to be particularly limited, but for example, the first trench capacitor 140 may include a first dielectric layer 143 and first and second electrodes 141 and 142 with the first dielectric layer 143 interposed therebetween, and the second trench capacitor 160 may include a second dielectric layer 163 and third and fourth electrodes 161 and 162 with the second dielectric layer 163 interposed therebetween.

The first electrode 141 may conformally cover one surface of the first interlayer 121 and inner walls of the plurality of first trenches TR1, and the third electrode 161 may conformally cover one surface of the second interlayer 122 and inner walls of the plurality of second trenches TR2. The first electrode 141 and the second electrode 142 may be disposed to oppose each other with the first dielectric layer 143 interposed therebetween, and the third electrode 161 and the fourth electrode 162 may be disposed with the second dielectric layer 163 interposed therebetween, thereby forming the first and trench capacitors 140 and 160 having a metal-insulator-metal (MIM) structure. Voltages having different polarities may be applied between the first electrode 141 and the second electrode 142, and voltages having different polarities may be applied between the third electrode 161 and the fourth electrode 162, thereby forming capacitances of the first and second trench capacitors 140 and 160.

The first to fourth electrodes 141, 142, 161, and 162 may include, for example, metal, metal oxide, metal nitride, metal oxynitride, doped polysilicon, and some other suitable conductive materials or combinations thereof. The first to fourth electrodes 141, 142, 161, and 162 may include, for example, copper (Cu), titanium (Ti), titanium (Ti) nitride, tantalum (Ta), and tantalum (Ta) nitride. However, the present disclosure is not limited thereto.

The first and second dielectric layers 143 and 163 may include, for example, at least one of silicon oxide, zirconium oxide, hafnium oxide, niobium oxide, titanium oxide, lanthanum oxide, tantalum oxide, lithium oxide, and aluminum oxide. However, the present disclosure is not limited thereto. In addition, the first and second dielectric layers 143 and 163 may be formed as a composite layer in which a plurality of metal oxides are stacked to improve electrical leakage properties. For example, the first and second dielectric layers 143 and 163 may be zirconium oxide-aluminum oxide-zirconium oxide may be sequentially stacked.

In an example embodiment, the capacitor component 100 may include a first cover layer 131 covering the first trench capacitor 140 and a second cover layer 132 covering the second trench capacitor 160. The first and second cover layers 131 and 132 may basically serve to protect the first and second trench capacitors 140 and 160. Referring to FIGS. 2 to 4, an internal empty space of the first trench TR1 may be filled with the first cover layer 131, and an internal empty space of the second trench TR2 may be filled with the second cover layer 132.

The cover layers 131 and 132 may include a material the same as that of the interlayers 121 and 122, but the present disclosure is not limited thereto. The first interlayer 121 and the first cover layer 131 may include different materials, and the second interlayer 122 and the second cover layer 132 may include different materials, as necessary. As will be described below, the first cover layer 131 may be formed integrally with the first dielectric layer 143, and the second cover layer 132 may be formed integrally with the second dielectric layer 163. Thus, in order to secure a high-K dielectric, the cover layers 131 and 132 may include a high-K dielectric material with a dielectric constant higher than that of the interlayers 121 and 122. As an example, the interlayers 121 and 122 may include silicon oxide, and the cover layers 131 and 132 may include hafnium oxide, but the present disclosure is not limited thereto.

Referring to FIG. 2, the through-vias 151 and 152 may pass through the substrate 110 to connect the first trench capacitor 140 and the second trench capacitor 160 to each other. More specifically, the through-vias 151 and 152 may include a first through-via 151 connecting the first electrode 141 and the third electrode 161 to each other, and a second through-via 152 connecting the second electrode 142 and the fourth electrode 162 to each other, the second through-via 152 disposed to be spaced apart from the first through-via.

The through-vias 151 and 152 may be filled with conductive materials 181 and 182, and thus the first trench capacitor 140 and the second trench capacitor 160 may be electrically connected to each other in parallel. That is, a capacitance of the capacitor component 100 may be a sum of individual capacitances of the first and second trench capacitors 140 and 160 connected to each other in parallel, thereby improving capacitance per unit area.

The through-vias 151 and 152 may have inclined side surfaces such that a width thereof increases or decreases from the first surface 101 to the second surface 102, due to an aspect ratio thereof, but the present disclosure is not limited thereto. It may be sufficient as long as the conductive materials 181 and 182 to include metal or another suitable conductive material, and the conductive materials 181 and 182 may include copper (Cu), titanium (Ti), titanium (Ti) nitride, and the like, but the present disclosure is not limited thereto.

In an example embodiment, the capacitor component 100 may further include first and second connection vias CV1 and CV2 passing through the first interlayer 121, the first and second connection vias CV1 and CV2 disposed to be spaced apart from each other with the first trench TR1 interposed therebetween, and third and fourth connection vias CV3 and CV4 passing through the second interlayer 122, the third and fourth connection vias CV3 and CV4 disposed to be spaced apart from each other with the second trench TR2 interposed therebetween. The through-vias 151 and 152 may connect the first trench capacitor 140 and the second trench capacitor 160 to each other through the first to fourth connection vias CV1, CV2, CV3, and CV4.

Specifically, the first and second electrodes 141 and 142 may extend to interiors of the first and second connection vias CV1 and CV2, respectively, and the third and fourth electrodes 161 and 162 extend to interiors of the third and fourth connection vias CV3 and CV4, respectively. In this case, the first through-via 151 may connect, to each other, the first electrode 141 disposed in the first connection via CV1 and the third electrode 161 disposed in the third connection via CV3. The second through-via 152 may connect the second electrode 142 disposed in the second connection via CV2 and the fourth electrode 162 disposed in the fourth connection via CV4. Although not illustrated, conductive pads, connecting the trench capacitors 140 and 160 and the conductive materials 181 and 182 to each other, may be disposed at upper ends and lower ends of the through-vias 151 and 152.

As illustrated in FIGS. 2 and 3, the first electrode 141 may be disposed on an inner wall of the first connection via CV1, and a portion of the interior of the first connection via CV1, excluding a space in which the first electrode 141 is disposed, may be filled with the first cover layer 131. The second electrode 142 may be disposed on an inner wall of the second connection via CV2, and a portion of the interior of the second connection via CV2, excluding a space where the second electrode 142 is disposed, may be filled with the first cover layer 131.

In addition, according to a process to be described below, the second connection via CV2 may be formed after the first dielectric layer 143 and the second electrode 142 are formed, such that a height of the second connection via CV2 in the first direction may be greater than a height of the first connection via CV1 in the first direction. That is, one end of the first connection via CV1 may be disposed on a level closer to the first surface 101 than one end of the second connection via CV2. Here, the one end of the first connection via CV1 and the one end of the second connection via CV2 may refer to ends spaced apart from the first surface 101. From the same perspective, the height of the fourth connection via CV4 in the first direction DR1 may be greater than the height of the third connection via CV3 in the first direction DR1. That is, one end of the third connection via CV3 may be disposed on a level closer to the second surface 102 than one end of the fourth connection via CV4. Here, the one end of the third connection via CV3 and the one end of the fourth connection via CV4 may refer to ends spaced apart from the second surface 102.

As illustrated in FIG. 3, the first connection via CV1 and the second connection via CV2 may each have a shape extending in the third direction DR3, but the present disclosure is not limited thereto. For example, as illustrated in FIG. 4, a plurality of first connection vias CV1 and a plurality of second connection vias CV2 may be disposed, the plurality of first connection vias CV1 may be disposed to be spaced apart from each other in the third direction DR3, and the plurality of second connection vias CV2 may be disposed to be spaced apart from each other in the third direction DR3.

First and second external electrodes 161 and 162, respectively connected to the first electrode 141 and the second electrode 142, may be disposed on the first cover layer 131. The first external electrode 161 may be electrically connected to the first electrode 141 through a first interconnection layer 171 disposed in the first cover layer 131, and the second external electrode 162 may be electrically connected to the second electrode 142 through a second interconnection layer 172 disposed in the first cover layer 131. Materials included in the external electrodes 161 and 162 and the interconnection layers 171 and 172 does not need to be particularly limited, and it may be sufficient as long as metal or another suitable conductive material are included.

The number, size, and aspect ratio of the interconnection layers 171 and 172 do not need to be particularly limited. It may be sufficient as long as lower surfaces of the first external electrode 161 and the second external electrode 162 are disposed to be coplanar with each other. However, according to a process to be described below, an end of the second electrode 142 may be disposed on a level closer to the lower surfaces of the external electrodes 161 and 162 than an end of the first electrode 141, such that a height of the second interconnection layer 172 in the first direction DR1 may be less than a height of the first interconnection layer 171 in the first direction DR1.

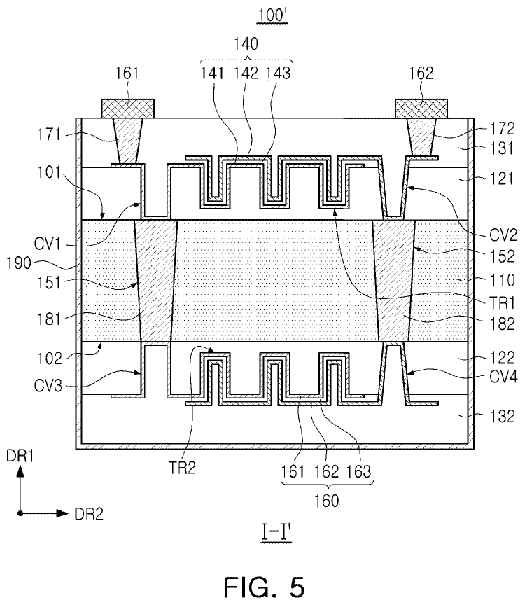

FIG. 5 is a modification of FIG. 2. Referring to FIG. 5, a capacitor component 100′ according to an example embodiment may include a molding portion 190 covering at least a portion of an external surface of a substrate 110. More preferably, the molding portion 190 may cover the external surfaces of the substrate 110, interlayers 121 and 122, and cover layers 131 and 132, and a lower surface of the cover layer 132. The molding portion 190 may serve to protect the substrate 110, the interlayers 121 and 122, and the cover layers 131 and 132. The molding portion 190 may be formed, for example, by transfer molding a resin such as an epoxy resin or the like.

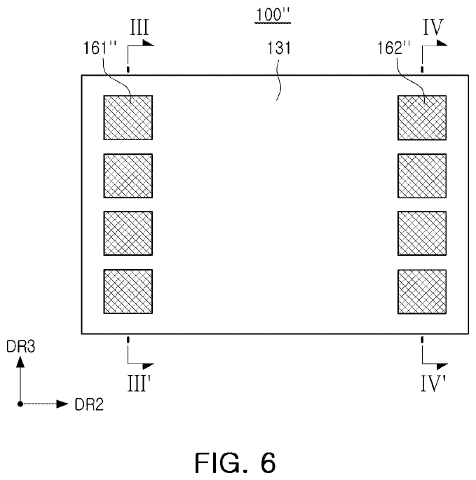

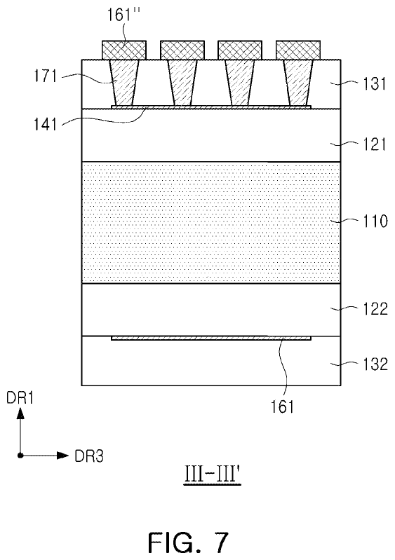

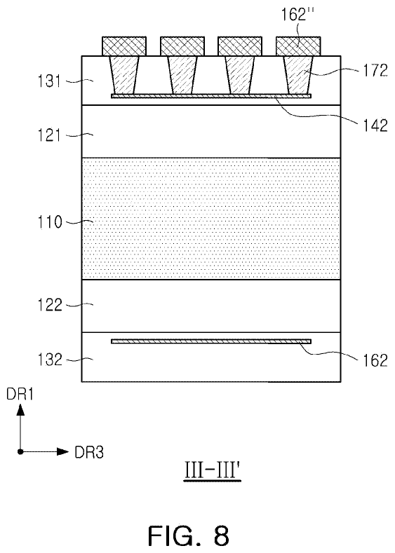

FIG. 6 is a schematic plan view of a capacitor component according to another example embodiment of the present disclosure. FIG. 7 is a schematic cross-sectional view taken along line III-III′ of FIG. 6. FIG. 8 is a schematic cross-sectional view taken along line IV-IV′ of FIG. 6.

Referring to FIGS. 6 to 8, a plurality of first external electrodes 161″ and a plurality of second external electrodes 162″ may each be disposed. As illustrated in FIG. 7, a plurality of first external electrodes 161″ may be connected to one first electrode 141. In addition, as illustrated in FIG. 8, the plurality of second external electrodes 162″ may be connected to one second electrode 142. In such a manner, the number of the first external electrodes 161″ and the second external electrodes 162″ may be increased to reduce a distance between the first external electrodes 161″ in a third direction DR3 and a distance between the second external electrodes 162″ in the third direction DR3, thereby reducing ESL of the capacitor component 100″.

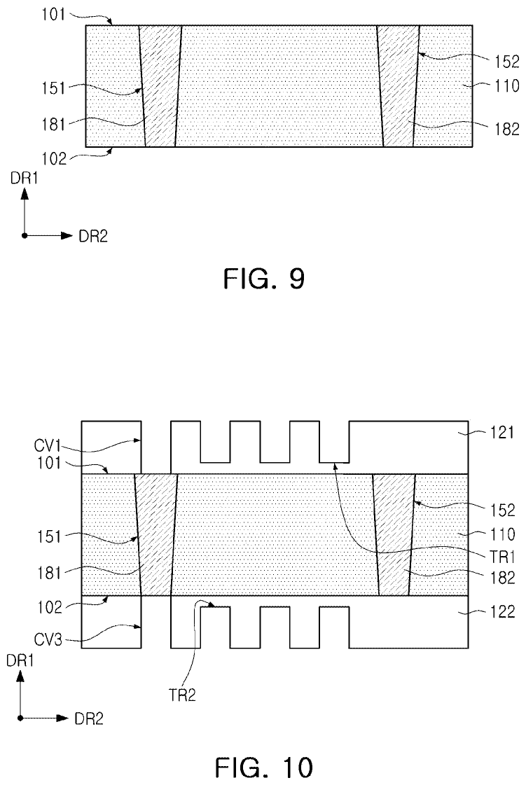

FIGS. 9 to 15 are cross-sectional views of main processes of a method of manufacturing a capacitor component according to an example embodiment of the present disclosure. Hereinafter, an example method of manufacturing the capacitor component 100 according to an example embodiment of the present disclosure will be described with reference to FIGS. 9 to 15.

First, referring to FIG. 9, a substrate 110 may be prepared, and then through-vias 151 and 152 may be formed using a laser drill or the like. Subsequently, conductive materials 181 and 182 may be deposited in the through-vias 151 and 152 using a plating method or sputtering method.

Subsequently, as illustrated in FIG. 10, a first interlayer 121 and a second interlayer 122 may be formed on a first surface 101 and a second surface 102 of the substrate 110, respectively. The interlayers 121 and 122 may be formed by depositing an insulating material or may be formed as an oxide film of the substrate 110. Thereafter, a portion of the interlayers 121 and 122 may be etched using a mask pattern and etching equipment to form a first trench TR1 and a second trench TR2 extending toward the substrate 110 in a first direction DR1. In addition, first and second connection vias CV1 and CV2 may be formed by etching a portion of the interlayers 121 and 122 formed on a first through-via 151 until a first conductive material 181 is exposed.

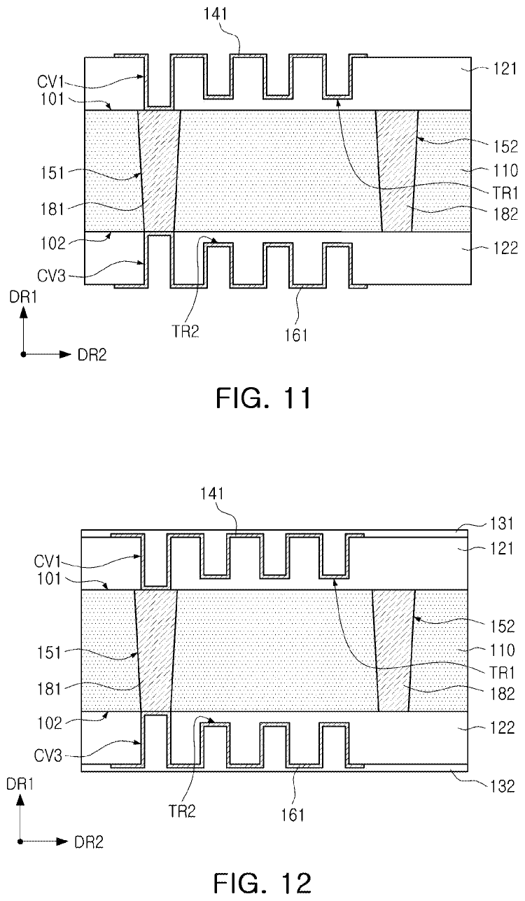

Subsequently, as illustrated in FIG. 11, a first electrode 141 and a third electrode 161 may be formed using an atomic layer deposition (ALD) or atomic vapor deposition (AVD) process. The first electrode 141 may be conformally formed along one surface of the first interlayer 121, an inner wall of the first trench TR1, and an inner wall of the first connection via CV1, and the third electrode 161 may be conformally formed along one surface of the second interlayer 122, an inner wall of the second trench TR2, and an inner wall of the second connection via CV2.

Subsequently, as illustrated in FIG. 12, an insulating material, the same as or different from that of the interlayers 121 and 122, may be deposited on the first and second interlayers 121 and 122, respectively, to partially form the first cover layer 131 and the second cover layer 132. In this case, the first and second cover layers 131 and 132, disposed on the first electrode 141 and the third electrode 161, may later serve as a dielectric layer forming a capacitance. However, the present disclosure is not limited thereto, and a material, different from that of the cover layers 131 and 132, may be deposited on the interlayers 121 and 122 to form a dielectric layer.

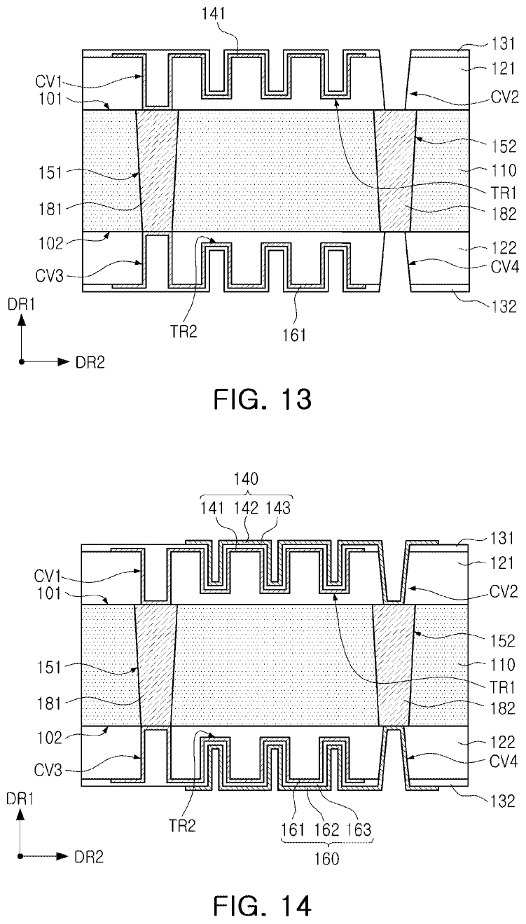

Subsequently, as illustrated in FIG. 13, a portion of the cover layers 131 and 132, filled in the first and second trenches TR1 and TR2, and a portion of the cover layers 131 and 132, deposited on a second through-via 152, may be etched. In this case, a portion of the cover layers 131 and 132, deposited on the second through-via 152, may be etched until a second conductive material 182 is exposed to form second and fourth connection vias CV2 and CV4.

Subsequently, as illustrated in FIG. 14, a second electrode 142 and a fourth electrode 162 may be formed using an atomic layer deposition (ALD) or atomic vapor deposition (AVD) process. In this case, a first cover layer, disposed between the first electrode 141 and the second electrode 142, may serve as a first dielectric layer 143, and a second cover layer, disposed between the third electrode 161 and the fourth electrode 162, may serve as a second dielectric layer 163. Accordingly, the first dielectric layer 143 and the first cover layer 131 may be integrally formed, and the second dielectric layer 163 and the second cover layer 132 may be integrally formed, but the present disclosure is not limited thereto.

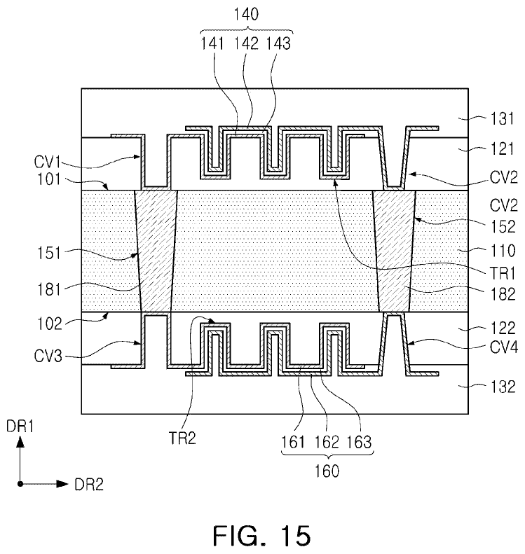

Subsequently, as illustrated in FIG. 15, the cover layers 131 and 132 may be formed by additionally depositing an insulating material, as previously designed. Finally, as illustrated in FIG. 2, a portion of the cover layers 131 and 132 may be etched to form a first interconnection layer 171, connected to the first electrode 141, and a second interconnection layer 172, connected to the second electrode 142, and first and second external electrodes 161 and 162 may be formed on the first and second interconnection layers 71 and 172, respectively, to manufacture the capacitor component 100 of FIG. 2.

However, the present disclosure is not limited thereto. A first interlayer 121, a first trench capacitor 140, and a first cover layer 131 may be formed on the first surface 101 of the substrate 110. Then, the substrate 110 may be turned over to form a second interlayer 122, a second trench capacitor 160, and a second cover layer 132 thereon. Specific processes and an order thereof may vary depending on an arrangement type of each component.

While example embodiments have been illustrated and described above, it will be apparent to those skilled in the art that modifications and variations could be made without departing from the scope of the present disclosure as defined by the appended claims.

In addition, the term “an example embodiment” used herein does not refer to the same example embodiment, and is provided to emphasize a particular feature or characteristic different from that of another example embodiment. However, example embodiments provided herein are considered to be able to be implemented by being combined in whole or in part one with one another. For example, one element described in a particular example embodiment, even if it is not described in another example embodiment, may be understood as a description related to another example embodiment, unless an opposite or contradictory description is provided therein.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

What is claimed is:

1. A capacitor component comprising:
a substrate having first and second surfaces opposing each other;
a first interlayer disposed on the first surface of the substrate, the first interlayer including a first trench;
a first trench capacitor disposed in the first trench;
a second interlayer disposed on the second surface of the substrate, the second interlayer including a second trench;
a second trench capacitor disposed in the second trench; and
a through-via passing through the substrate to connect the first trench capacitor and the second trench capacitor to each other.

2. The capacitor component of claim 1, wherein
the first trench capacitor includes a first dielectric layer and first and second electrodes disposed with the first dielectric layer interposed therebetween, and
the second trench capacitor includes a second dielectric layer and third and fourth electrodes disposed with the second dielectric layer interposed therebetween.

3. The capacitor component of claim 2, wherein the through-via includes:
a first through-via, connecting the first electrode and the third electrode to each other, and
a second through-via, connecting the second electrode and the fourth electrode to each other.

4. The capacitor component of claim 2, wherein the first and second dielectric layers are spaced apart from the through-via.

5. The capacitor component of claim 1, wherein the through-via is filled with a conductive material.

6. The capacitor component of claim 4, further comprising:
first and second connection vias passing through the first interlayer, the first and second connection vias disposed to be spaced apart from each other with the first trench interposed therebetween, and
third and fourth connection vias passing through the second interlayer, the third and fourth connection vias disposed to be spaced apart from each other with the second trench interposed therebetween.

7. The capacitor component of claim 6, wherein
the first and second electrodes extend to interiors of the first and second connection vias, respectively,
the third and fourth electrodes extend to interiors of the third and fourth connection vias, respectively,
the first through-via connects the first electrode disposed in the first connection via and the third electrode disposed in the third connection via to each other, and
the second through-via connects the second electrode disposed in the second connection via and the fourth electrode disposed in the fourth connection via to each other.

8. The capacitor component of claim 1, further comprising:
a first cover layer covering the first trench capacitor and a second cover layer covering the second trench capacitor.

9. The capacitor component of claim 8, wherein
the first interlayer and the first cover layer include different materials, and
the second interlayer and the second cover layer include different materials.

10. The capacitor component of claim 1, wherein
the first and second surfaces oppose each other in a first direction,
the first interlayer includes a plurality of first trenches,
the plurality of first trenches are disposed to be spaced apart from each other in a second direction, intersecting the first direction, and
each of the plurality of first trenches extends in a third direction, intersecting the first direction and the second direction.

11. The capacitor component of claim 1, wherein
the first and second surfaces oppose each other in a first direction,
the first interlayer includes a plurality of first trenches, and
the plurality of first trenches are disposed to be spaced apart from each other in a second direction, intersecting the first direction, and are disposed to spaced apart from each other in a third direction, intersecting the first direction and the second direction.

12. The capacitor component of claim 2, further comprising:
a first cover layer covering the first trench capacitor, and
first and second external electrodes disposed on the first cover layer, the first and second external electrodes respectively connected to the first electrode and the second electrode.

13. The capacitor component of claim 12, wherein the first and second external electrodes respectively include a plurality of external electrodes.

14. The capacitor component of claim 12, wherein the first cover layer and the first dielectric layer include the same material.

15. The capacitor component of claim 14, wherein the same material of the first cover layer and the first dielectric layer has a dielectric constant higher than that of the first interlayer.

16. The capacitor component of claim 1, further comprising:
a molding portion covering at least a portion of an external surface of the substrate.

17. The capacitor component of claim 1, wherein only a conductive material is disposed in the through-via.
